(19) United States
(12) Patent Application Publication
(10) Pub. No.: US 2010/0068893 A1
(43) Pub. Date: Mar. 18, 2010

(54) FILM DEPOSITION APPARATUS, FILM DEPOSITION METHOD, AND COMPUTER READABLE STORAGE MEDIUM

(75) Inventors: HITOSHI KATO, Oshu-Shi (JP); Kazuteru Obara, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/559,616

(22) Filed: Sep. 15, 2009

(30) Foreign Application Priority Data
Sep. 17, 2008 (JP) 2008-238439

(51) Int. Cl. H01L 21/302; C23C 16/00; B05C 11/10

(52) U.S. Cl. 438/758; 118/730; 118/697; 257/E21.214

(57) ABSTRACT

A film deposition apparatus includes a reaction chamber evacuatable to a reduced pressure; a substrate holding portion rotatably provided in the reaction chamber and configured to hold a substrate; a first reaction gas supplying portion configured to flow a first reaction gas from an outer edge portion toward a center portion of the substrate holding portion; a second reaction gas supplying portion configured to flow a second reaction gas from an outer edge portion toward a center portion of the substrate holding portion; a separation gas supplying portion configured to flow a separation gas from an outer edge portion toward a center portion of the substrate holding portion, the separation gas supplying portion being arranged between the first and the second gas supplying portions; and an evacuation portion located in the center portion of the substrate holding portion in order to evacuate the first, the second, and the separation gases.

### CROSS-REFERENCE TO RELATED APPLICATIONS

The present application is based on Japanese Patent Application No. 2008-238439 filed with the Japanese Patent Office on Sep. 17, 2008, the entire contents of which are hereby incorporated herein by reference.

### BACKGROUND OF THE INVENTION

1. Field of the Invention

The present invention relates to a film deposition apparatus and a film deposition method for depositing a film on a substrate by carrying out plural cycles of supplying in turn at least two source gases to the substrate in order to form plural layers of a reaction product, and a computer readable storage medium storing a computer program for carrying out the film deposition method.

2. Description of the Related Art

Along with further miniaturization of a circuit pattern in semiconductor devices, various films constituting the semiconductor devices are required to be thinner and more uniform. As a film deposition method that can address such requirements, a so-called Molecular Layer Deposition (MLD), which is also called Atomic Layer Deposition (ALD), has been known that can provide accurately controlled film thickness and excellent uniformity.

In this film deposition method, a first reaction gas is supplied to a reaction chamber where a substrate is housed to allow first reaction gas molecules to be adsorbed on the substrate; and after the first reaction gas is purged from the reaction chamber, a second reaction gas is supplied to a reaction chamber to allow second reaction gas molecules to be adsorbed on the substrate, thereby causing the reaction gas molecules to react with each other and producing a monolayer of the reaction products on the substrate. Then, the second reaction gas is purged from the reaction chamber, and the above procedures are repeated a predetermined number of times, thereby depositing a film having a predetermined thickness. Because the first and the second reaction gas molecules adsorbed one over the other on the substrate react with each other, which forms a monolayer of the reaction product on the substrate, film thickness and uniformity may be controlled at a monolayer level.

It has been known that such a film deposition method is carried out in a hot-wall batch-type film deposition apparatus (Patent Documents 1 and 2).

Patent Document 1: Japanese Patent Application Laid-Open Publication No. 2006-32610.

Patent Document 2: Japanese Patent Application Laid-Open Publication No. 2000-294511.

### SUMMARY OF THE INVENTION

In a batch-type chemical vapor deposition (CVD) apparatus, a process tube tends to be larger because several ten through one hundred wafers are housed in the process tube. Therefore, it takes a long time to purge the process tube when a first source gas is switched to a second source gas and vice versa. In addition, because the number of cycles may reach several hundred, it takes a longer time to carry out one run of film deposition, which may cause a problem of an increased turn-around-time (TAT). Moreover, because of a longer process time, a large amount of gas is consumed, leading to an increased production cost. Furthermore, because the gases are switched a lot of times, valves may be replaced many times, leading to an increased maintenance cost and thus an increased production cost.

The present invention has been made in view of the above, and provides a film deposition apparatus that can reduce a process time, a film deposition method using the film deposition apparatus, and a computer readable storage medium that stores a computer program for causing the film deposition apparatus to carry out the film deposition method.

A first aspect of the present invention provides a film deposition apparatus including a reaction chamber evacuatable to a reduced pressure; a wafer holding portion rotatably provided in the reaction chamber and configured to hold a wafer; a first reaction gas supplying portion configured to flow a first reaction gas from an outer edge portion toward a center portion of the wafer holding portion; a second reaction gas supplying portion configured to flow a second reaction gas from an outer edge portion toward a center portion of the wafer holding portion; a separation gas supplying portion configured to flow a separation gas from an outer edge portion toward a center portion of the wafer holding portion, the separation gas supplying portion being arranged between the first and the second gas supplying portions; and an evacuation portion located in the center portion of the wafer holding portion in order to evacuate the first reaction gas, the second reaction gas, and the separation gas.

A second aspect of the present invention provides a film deposition method comprising steps of: placing a wafer on a wafer holding portion rotatably provided in a reaction chamber evacuatable to a reduced pressure; rotating the wafer holding portion on which the wafer is placed; flowing a first reaction gas from an outer edge portion toward a center portion of the wafer holding portion from a first reaction gas supplying portion; flowing a second reaction gas from an outer edge portion toward a center portion of the wafer holding portion from a second reaction gas supplying portion; flowing a separation gas from an outer edge portion toward a center portion of the wafer holding portion from a separation gas supplying portion arranged between the first and the second reaction gas supplying portions; and evacuating the first reaction gas, the second reaction gas, and the separation gas from the center portion of the wafer holding portion.

A third aspect of the present invention provides a computer readable storage medium storing a program that causes the film deposition apparatus of the first aspect to carry out the film deposition method.

### BRIEF DESCRIPTION OF THE DRAWINGS

FIG. 1 is a schematic view illustrating a film deposition apparatus according to an embodiment of the present invention;

FIG. 2 is a schematic view illustrating a reaction chamber of the film deposition apparatus shown in FIG. 1;

FIG. 3 is an explanatory view of a disk boat of the reaction chamber shown in FIG. 2;

FIG. 4 is an explanatory view of an inner evacuation port of the reaction chamber shown in FIG. 2;

FIG. 5 is an explanatory view of a positional relationship among the disk boat, gas supplying pipes, and the inner evacuation port and a gas flow pattern in the reaction chamber shown in FIG. 2,

FIG. 6 illustrates the disk boat lowered from the reaction chamber by an elevation unit; and

FIG. 7 is a flowchart explaining a film deposition method according to an embodiment of the present invention.

### DETAILED DESCRIPTION OF THE PREFERRED EMBODIMENT

According to an embodiment of the present invention, there is provided a film deposition apparatus that can reduce a process time, a film deposition method using the film deposition apparatus, and a computer readable storage medium that stores a computer program for causing the film deposition apparatus to carry out the film deposition method.

Non-limiting, exemplary embodiments of the present invention will now be described with reference to the accompanying drawings. In the drawings, the same or corresponding reference numbers and symbols are given to the same or corresponding members or components. It is noted that the drawings are illustrative of the invention, and there is no intention to indicate scale or relative proportions among the members or components. Therefore, the specific size should be determined by a person having ordinary skill in the art in view of the following non-limiting embodiments. In addition, while a film deposition apparatus and method according to an embodiment of the present invention are explained in the following taking an example of depositing a silicon oxide film, a film deposition apparatus and method according to an embodiment of the present invention are applicable not only to deposition of the silicon oxide film but also films of various other materials described below.

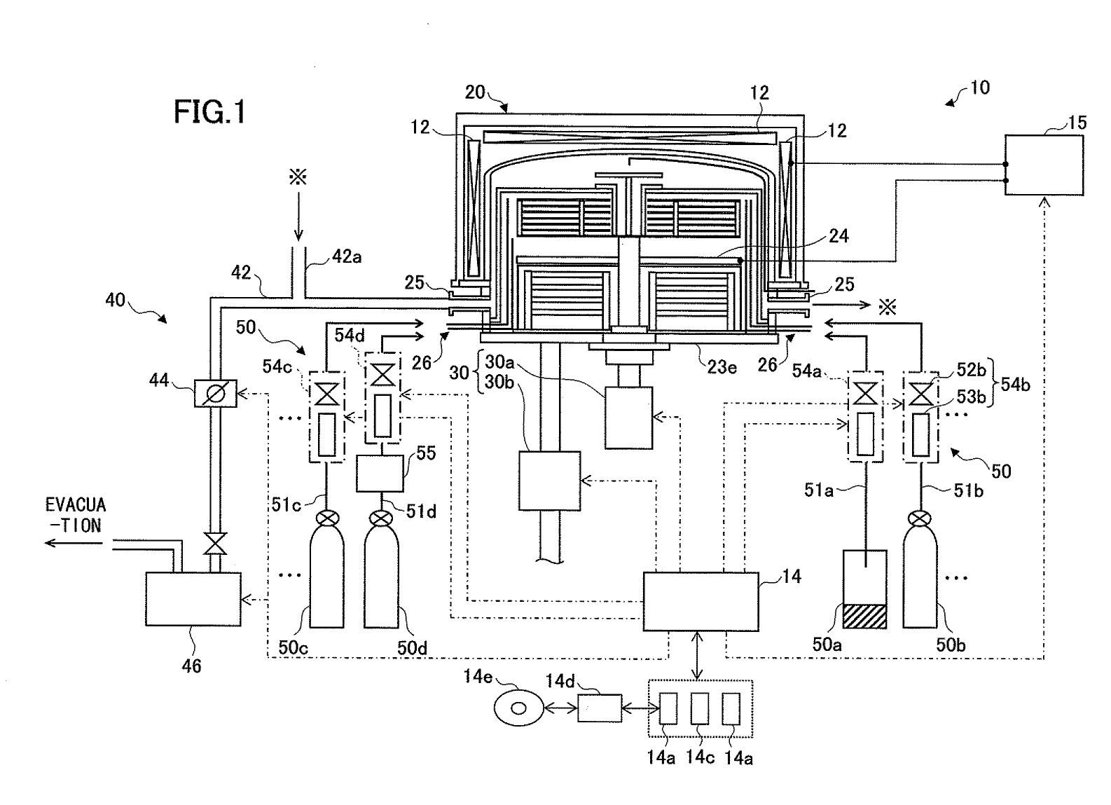

FIG. 1 is a schematic view illustrating a film deposition apparatus according to an embodiment of the present invention. The film deposition apparatus is configured as a vertical batch-type apparatus. As shown, a film deposition apparatus 10 includes a reaction chamber 20, a driving unit 30 configured to load/unload a wafer boat (described later) into/from the reaction chamber 20 and to rotate the wafer boat, an evacuation system 40 configured to evacuate the reaction chamber 20 to a reduced pressure, a gas supplying system serving as a gas supplying source that introduces gases to the reaction chamber 20, and a controller 14 configured to control film deposition.

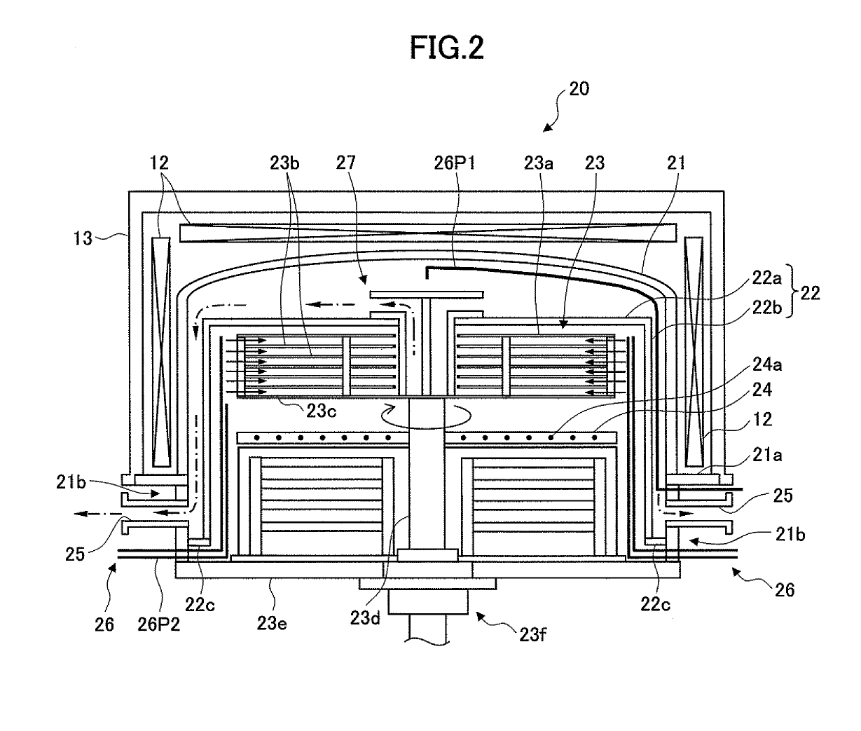

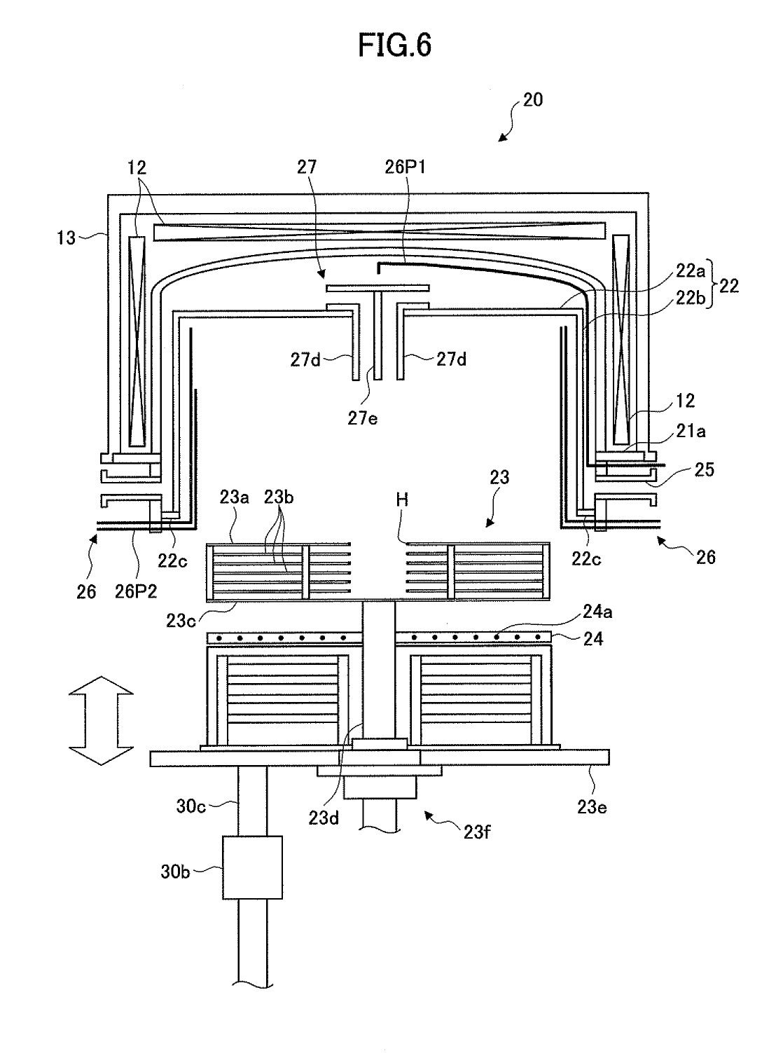

First, the reaction chamber 20 is explained with reference to FIGS. 2 through 6. As shown in FIG. 2, the reaction chamber 20 includes an outer tube 21 having substantially a cylindrical shape with a closed top (bell-jar shape), an inner tube 22 arranged inside the outer tube 21 and having a cylindrical shape with a closed top, a disk boat 23 configured to support plural wafer disks 23b, an inner heater 24 arranged inside the inner tube 22 and below the disk boat 23 and configured to heat the disk boat 23 from below, plural gas supplying pipes 26 extending along an inner wall of the inner tube 22 and configured to eject corresponding gases, evacuation ports 25 to be used to evacuate the outer tube 21 to a reduced pressure by the evacuation system 40, an outer heater 12 configured to surround a side wall surface of the outer tube 21 and cover a top portion of the outer tube 21, and a heat shield 13 configured to cover the outer heater 12.

The outer tube 21 is made of, for example, quartz, and hermetically attached at the bottom on an annular flange 21a via a seal member such as an O-ring (not shown). The flange 21a is placed on a flattened cylindrical skirt member 21b. Another seal member such as an O-ring (not shown) is provided between the flange 21a and the skirt member 21b, and thus the flange 21a is hermetically sealed with respect to the skirt member 21b. In addition, the skirt member 21b is made of, for example, stainless steel, and has through holes in a side wall through which the evacuation ports 25 are inserted.

The inner tube 22 is made of, for example, quartz or silicon carbide, and composed of a ceiling member 22a having a disk shape and a cylindrical portion 22b. The ceiling member 22a has an opening at the center, and an inner evacuation port 27 (described below), that allows gaseous communication between the inside and the outside of the inner tube 22, is inserted through the opening. In addition, the cylindrical portion 22b of the inner tube 22 is attached at the bottom on an annular flange 22c via a seal member (not shown). The flange 22c has substantially the same or a slightly smaller diameter than the inner diameter of the skirt member 21b, and is fixed on the inner circumferential surface of the skirt member 21b.

The disk boat 23 includes a circular upper plate 23a, a circular lower plate 23c, and plural wafer disks 23b arranged between the upper and the lower plates 23a, 23b. The upper plate 23a and the wafer disks 23b are provided with openings (described later) at the centers, and the inner evacuation port 27 can be inserted through not only the opening of the ceiling member 22a of the inner tube 22 but also these openings of the upper plate 23a and the wafer disks 23b. As shown in FIG. 2, a supporting rod 23d is attached on the lower center portion of the lower plate 23c of the disk boat 23 and supported by, for example, a rotary feedthrough 23f of a magnetic fluid seal type provided in a lower plate 23c of the reaction chamber 20. In addition, as shown in FIG. 1, the supporting rod 23d extends below the rotary feedthrough 23f and is coupled at the bottom end with a rotary motor 30a, which rotates the supporting rod 23d and thus the disk boat 23 supported by the supporting rod 23d.

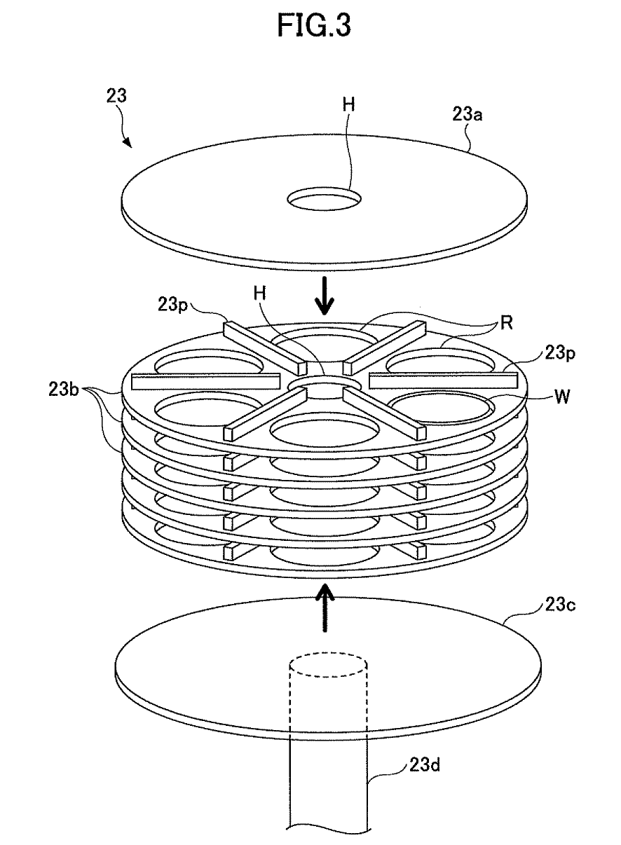

Referring to FIG. 3, the disk boat 23 is further explained. In FIG. 3, the upper plate 23a and the lower plate 23c are removed from the wafer disks 23b in order to better illustrate a configuration of the disk boat 23. As shown, the disk boat 23 includes five wafer disks 23b stacked one on another with a predetermined vertical clearance between every two adjacent wafer disks 23b. The wafer disk 23b is provided with six wafer receiving portions R in which corresponding six wafers W (only one wafer W is shown in FIG. 3) are placed. The wafer receiving portions R may be a concave portion having a diameter slightly larger than the diameter of the wafer W and a depth having substantially the same dimension as a thickness of the wafer W. In addition, the wafer receiving portions R are arranged at equal angular intervals of about 60° in the wafer disk 23b. In the illustrated example, 6 wafers can be placed on one wafer disk 23b. With this, the disk boat 23 can hold a total of 30 wafers W because the disk boat 23 has five wafer disks 23b. The clearance between the wafer disks 23b may be determined in accordance with a height of the reaction chamber 20, the number of the wafers W to be held by the wafer boat 23, kinds of gases to be used, and the like, and may specifically be in a range from about 5 mm through about 70 mm, or more preferably in a range from about 25 mm through about 50 mm.

Partitioning plates 23p extending along a radius direction of the wafer disk 23b are arranged between every two adjacent wafer receiving portions R on the wafer disk 23b. The partitioning plates 23p have a height equal to the clearance between the two vertically adjacent wafer disks 23b (the clearance between the topmost wafer disk 23b and the upper plate 23a). With this, an upper surface (having the wafer receiving portions R) of one wafer disk 23b, a lower surface of another wafer disk 23b (the upper plate 23a) above the one wafer disk 23b, and two adjacent partitioning plates 23p define a compartment. Each compartment includes one wafer receiving portion R, in which one wafer W is placed.

In addition, as described above, the openings H are made in the upper plate 23a and the wafer disks 23b, and the inner evacuation port 27 (FIG. 2) is inserted through the openings H.

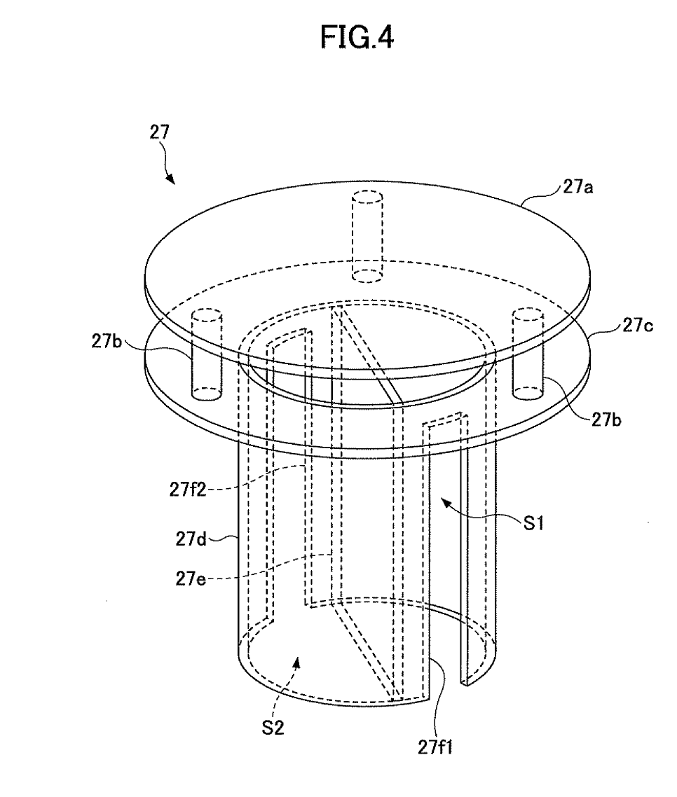

Referring to FIG. 4, the inner evacuation port 27 is explained. As shown in FIG. 4, the inner evacuation port 27 is composed of a circular plate 27a, an annular plate 27c coupled to the circular plate 27a by a pillar 27b, a cylindrical tube 27d engaged into an inner circumference of the annular plate 27c, and a planar plate 27e configured to divide an inner space of the cylindrical tube 27d into two semi-cylindrical spaces S1, S2. The cylindrical tube 27d is provided with two slits 27f1, 27f2 that oppose each other with a center axis of the cylindrical tube 27d therebetween and extend along a longitudinal direction of the cylindrical tube 27d. The slits 27f1, 27f2 are provided for the corresponding semi-cylindrical spaces S1, S2. As shown in FIG. 2, because the inner evacuation port 27 is arranged so that the annular plate 27c sits on the ceiling member 22a of the inner tube 22, the inside and the outside of the inner tube 22 are in gaseous communication with each other through the slit 27f1 and the semi-cylindrical space S1, and the slit 27f2 and the semi-cylindrical space S2.

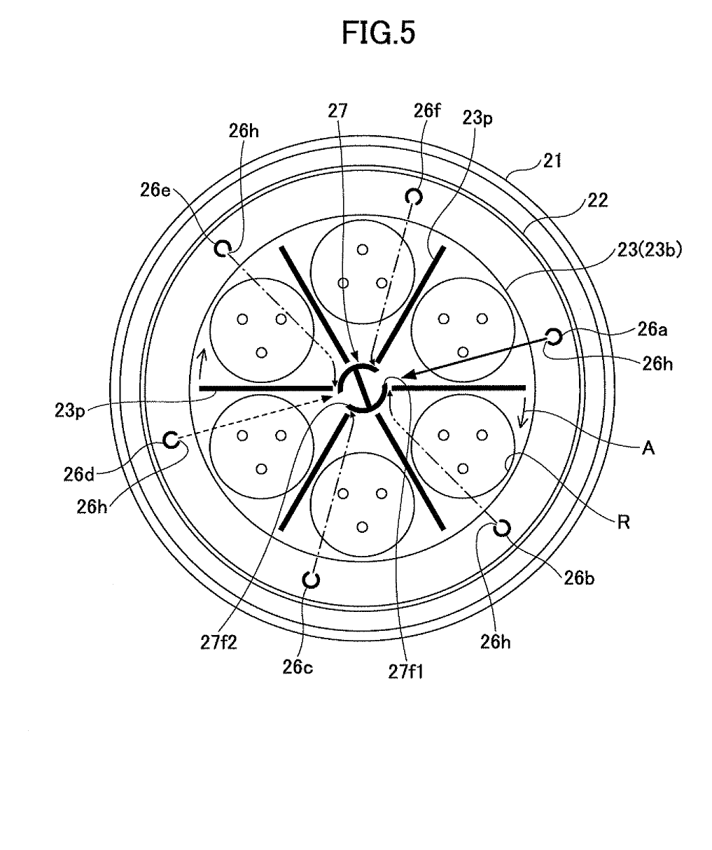

Referring to FIG. 2, the gas supplying pipes 26 hermetically penetrate through the skirt member 21b from outside, are bent upward in an L shape between the inner tube 22 and the disk boat 23, and extend upward along the inner wall of the inner tube 22 (the cylindrical portion 22b). The gas supplying tubes 26 are closed at the top ends, and provided with plural ejection holes 26H (see FIG. 5) at predetermined intervals over a predetermined range from the top ends. A gas is ejected from the ejection holes 26H toward the disk boat 23 (see a solid line arrow in FIG. 2). The ejection holes 26H are made with a distance equal to the clearance between the wafer disks 23b of the disk boat 23, so that a predetermined gas is supplied to spaces between every two vertically adjacent wafer disks 23b (the topmost wafer disk 23b and the upper plate 23a).

Next, a positional relationship among the gas supplying line 26, the disk boat 23 and the inner evacuation port 27, and a gas flow over the disk boat 23 are explained in reference to FIG. 5. FIG. 5 is a plan view illustrating a configuration inside the outer tube 21, and specifically one of the plural wafer disks 23b of the disk boat 23 for the sake of simplicity. The positional relationships of the other wafer disks 23b with respect to the gas supplying line 26 and the inner evacuation port 27 are the same. As shown in FIG. 5, the six gas supplying pipes 26a through 26f are arranged at equal angular intervals (about 60°) between the inner tube 22 and the disk boat 23 (wafer disks 23b). The gas supplying pipes 26a through 26f have the plural ejection holes 26h directed toward the center of the disk boat 23. In the illustrated example, a silicon-containing gas may be supplied from the gas supplying pipe 26a, and an oxygen-containing gas may be supplied from the gas supplying pipe 26d located symmetrically to the gas supplying pipes 26a with respect to the inner port 27. The ejection holes 26h of the gas supplying pipe 26a for supplying the source gas are directed toward the slit 27f1 of the inner evacuation port 27. Therefore, the source gas from the ejection holes 26h of the gas supplying pipe 26a flows along the upper surface of the wafer disk 23b (in every wafer disk 23b) into the inner evacuation port 27, as shown by a solid line arrow in FIG. 5. In addition, the ejection holes 26h of the gas supplying pipe 26d for supplying the oxidizing gas are directed toward the slit 27f2 of the inner evacuation port 27. Therefore, the oxidizing gas from the ejection holes 26h of the gas supplying pipe 26d flows along the upper surface of the wafer disk 23b (in every wafer disk 23b) into the inner evacuation port 27, as shown by a dotted line arrow in FIG. 5. While the disk boat 23 (wafer disks 23b) can be rotated as shown by an arrow A in FIG. 5, the inner evacuation port 27 cannot be rotated because the inner evacuation port 27 is placed on the ceiling member 22a of the inner tube 22. Therefore, when the disk boat 23 is rotated, the positional relationship between the slit 27f1 (27f2) of the inner evacuation port 27 and the gas supplying pipe 26a (26d) is not changed.

On the other hand, the inert gas or N₂ gas as a separation gas can be supplied from the gas supplying pipes 26b, 26c, 26e, 26f. As seen from FIG. 5, the inner evacuation port 27 is not provided with slits directed toward the ejection holes 26h of these gas supplying pipes 26b, 26c, 26e, 26f, in this embodiment. Therefore, when the N₂ gas is ejected from the gas supplying pipes 26b, 26c, 26e, 26f, the N₂ gas flows to the inner evacuation port 27 and along the outer circumferential surface of the inner evacuation port 27. Then, the N₂ gas flows through a gap between the inner evacuation port 27 and the partitioning plates 23p into the slits 27f1, 27f2.

As stated above, a flow of the silicon source gas from the gas supplying pipe 26a toward the slit 27f1 of the inner evacuation port 27, flows of the N₂ from the gas supplying pipes 26b, 26c toward the inner evacuation port 27, a flow of the oxidizing gas from the gas supplying pipe 26d toward the slit 27f2 of the inner evacuation port 27, and flows of the N₂ gas from the gas supplying pipes 26e, 26f are formed in a clockwise direction seen from the above, over each of the wafer disks 23b.

Referring back to FIG. 1, the gas supplying pipes 26 are connected to the gas supplying system 50. The gas supplying system 50 includes gas supplying sources 50a, 50b, 50c, 50d, . . . , gas lines 51a, 51b, 51c, 51d, . . . that connect the gas supplying sources 50a, 50b, 50c, 50d, . . . to the gas supplying pipes 26a, 26b, 26c, 26d, . . . , and gas controllers 54a, 54b, 54c, 54d, . . . provided in the gas lines 51a, 51b, 51c, 51d, . . . . The gas controller 54b includes an open/close valve 52b and a mass flow controller (MFC) 53b. The gas controllers 54a, 54c, 54d, . . . have the same configuration as the gas controller 54b, although reference numerals are omitted in FIG. 1.

The gas supplying source 50a may be, for example, but not limited to a bis(tertiary-butylamino) silane (BTBAS) supplier filled with BTBAS as the silicon-containing source gas. The gas line 51a connected at one end to the gas supplying source 50a is connected at the other end to the gas supplying pipe 26a, and thus the BTBAS gas is supplied to the gas supplying pipe 26a. The gas supplying source 50d may be, for example, but not limited to a gas cylinder filled with oxygen (O₂), and the gas line 51d is provided with an ozone generator 55, which generates ozone (O₃) gas from the O₂ gas. Therefore, the O₃ gas is supplied to the gas supplying pipe 26d.

In addition, the gas supplying sources 50b, 50c, . . . , except for the gas supplying sources 50a, 50d, may be gas cylinders filled with, for example, the inert gas or the N₂ gas, and thus the inert gas or the N₂ gas is supplied to the gas supplying pipes 26b, 26c, . . . through the gas lines 50b, 50c, . . . .

Moreover, the reaction chamber 20 is provided with a first purge gas supplying pipe 26P1, as shown in FIG. 2. The first purge gas supplying pipe 26P1 hermetically penetrates the skirt member 21b from the outside, is bent upward between the outer tube 21 and the inner tube 22, and extends along the inner wall surface of the outer tube 21. Then, the first purge gas supplying pipe 26P1 is bent substantially in a horizontal direction above the ceiling member 22a of the inner tube 22, extends along the inner ceiling surface of the outer tube 21 and reaches above the inner evacuation port 27. Finally, the first purge gas supplying pipe 26P1 is bent downward to the inner evacuation port 27. In addition, the first purge gas supplying pipe 26P1 is connected to a gas supplying source (not shown) outside the reaction chamber 20, and the inert gas or the N₂ gas as a purge gas is supplied from the gas supplying source. With these configurations, the inert gas or the N₂ gas is ejected toward the inner evacuation port 27 from the first purge gas supplying pipe 26P1. With such a purge gas, the gases flowing out from the inside to the outside of the inner tube 22 through the inner evacuation port 27 can be diluted by the inert gas or the N₂ gas from the first purge gas supplying pipe 26P1, and facilitated to be evacuated by the evacuation system 40.

In addition, the reaction chamber 20 is also provided with a second purge gas supplying pipe 26P2, as shown in FIG. 2. The second purge gas supplying pipe 26P2 hermetically penetrates the skirt member 21b from the outside, extends along the inner wall surface of the inner tube 22 between the inner tube 22 and the inner heater 24, and reaches below the lower plate 23c of the disk boat 23. The second purge gas supplying pipe 26P2 is closed at the top end and provided on the side with an ejection hole (not shown) directed toward the center of the inner tube 22. In addition, the second purge gas supplying pipe 26P2 is connected to a gas supplying source (not shown) outside the reaction chamber 20, and thus the inert gas or the N₂ gas as a purge gas is supplied from the gas supplying source and ejected toward the center of the inner tube 22. With these configurations, the inert gas or the N₂ gas is supplied to a space between the inner heater 24 and the disk boat 23, which prevents the source gas and the oxidizing gas from flowing into the space.

The gases flowing into the slits 27f1, 27f2 (FIGS. 4, 5) of the inner evacuation port 27 flow upward in the cylindrical tube 27d to the outside space of the inner tube 22, and further flows through a space between the inner tube 22 and the outer tube 21, and are evacuated through the evacuation ports 25 by the evacuation system 40, as shown by a dashed line arrow in FIG. 2. As shown in FIG. 1, the evacuation system 40 includes an evacuation pipe 42 connected to one of the evacuation ports 25, a branch pipe 42a that connects the evacuation pipe 42 to the other one of the evacuation ports 25, a pressure control valve 44 provided in the middle of the evacuation pipe 42, and a vacuum pump 46 such as a dry pump connected to the evacuation pipe 42. In addition, a vacuum gauge (not shown) is hermetically inserted into the inner tube 22, which enables a pressure in the inner tube 22 to be measured, and the pressure is controlled by the pressure control valve 44 in accordance with the measured pressure.

Incidentally, the wafers W (FIG. 3) housed in the disk boat 23 are heated by the outer heater 12 arranged to surround the outer circumference and the dome-shaped ceiling of the outer tube 21, and the inner heater 24 arranged below the disk boat 23 inside the inner tube 22. The outer heater 12 may be composed of a heating wire and the inner heater 24 may be composed of plural concentrically arranged ring heaters 24a (FIG. 2). The outer heater 12 and the inner heater 24 are electrically connected to a temperature controller 15 (FIG. 1) that supplies and controls electrical power to the heaters 12, 24 in order to control a temperature of the wafers W. The temperature of the wafers W is monitored by a temperature sensor (not shown) arranged near the disk boat 23, and controlled by the temperature controller 15 in accordance with the monitored temperature.

In addition, an elevation mechanism 30b coupled to a bottom plate 23e of the reaction chamber 20 can vertically move in unison the inner heater 24 arranged above the bottom plate 23e, the supporting rod 23d supported by the rotary feedthrough 23f attached in the bottom plate 23e, and the disk boat 23 supported by the supporting rod 23d. With this, the disk boat 23 can be loaded/unloaded into/from the inner tube 22.

In addition, gas supplying by the gas controller 54a, 54b, 54c, 54d, . . . , vertical movement of the elevation mechanism 30b, rotation of the disk boat 23 by the rotary motor 30a, pressure in the outer tube 21 by the pressure control valve 44, temperature of the wafer W heated by the inner heater 24 and the outer heater 12, and the like are managed by a control portion (FIG. 1). The control portion 14 may include a computer in order to cause the film deposition apparatus to carry out MLD deposition in accordance with a computer program. This program includes groups of instructions to cause the film deposition apparatus 10 to execute steps of, for example, a film deposition method described later. In addition, the control portion 14 is connected to a display unit 14a that displays recipes, process status and the like, a memory device 14b that stores the program and process parameters, and an interface device 14c that may be used along with the display unit 14a to edit the program and modify the process parameters. Moreover, the memory device 14b is connected to an input/output (I/O) device 14d through which the program, the recipes, and the like are loaded/unloaded from/to a computer readable storage medium 14e storing the program and the like. With this, the program and the recipe are loaded to the memory device 14b from the computer readable storage medium 14e in accordance with instruction input from the interface device 14c. Incidentally, the computer readable storage medium 14e may be a hard disk (including a portable hard disk), a compact disk (CD), a CD-R/RW, a digital versatile disk (DVD)-R/RW, a flexible disk, a universal serial bus (USB) memory, a semiconductor memory, and the like. In addition, the program and the recipe may be downloaded through a communication line to the memory device 14b.

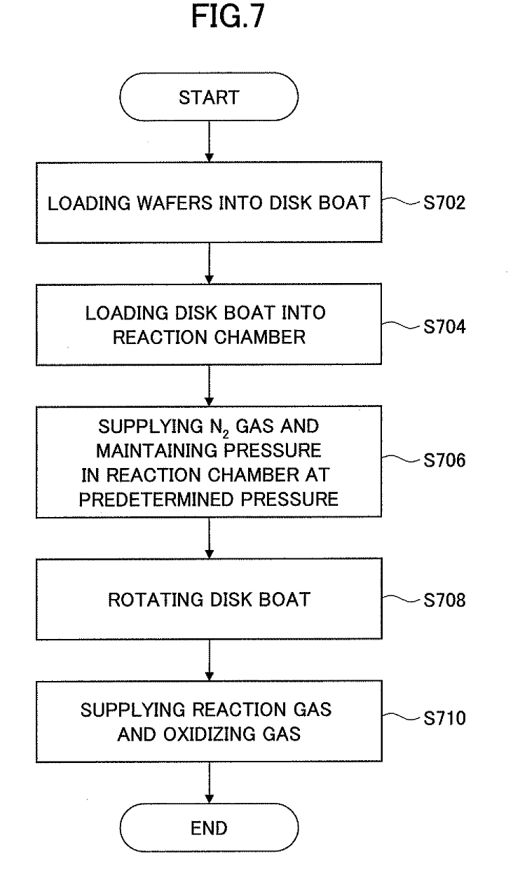

Next, a film deposition method according to an embodiment of the present invention is explained with reference to FIG. 7 and FIGS. 1 through 6. In the following, a film deposition process in which an MLD of silicon oxide is deposited on the wafer W using the BTBAS gas and the O₃ gas by the film deposition apparatus 10 is explained.

First, the bottom plate 23e, the rotary motor 30a, the inner heater 24 and the disk boat 23 are lowered by the elevation mechanism 30b, and the wafers W are placed on the disk boats 23 by a wafer loader (not shown) (Step S702). The wafers W are prepared in a predetermined cassette, and one of the wafers W is fetched from the cassette and placed in one of the wafer receiving portions R in one of the wafer disks 23b of the disk boat 23. Then, the disk boat 23 is rotated by 60° and a next one of the wafers W is placed in a next one of the wafer receiving portions R. Next, the wafers W are placed in all the wafer receiving portions R in one of the wafer disks 23b in such a manner. Subsequently, the same procedures are repeated until all the wafer receiving portions R in the disk boat 23 are occupied by the wafers W.

Next, the bottom plate 23e, the rotary motor 30a, the inner heater 24 and the disk boat 23 are raised by the elevation mechanism 30b, so that the disk boat 23 and the inner heater 24 are loaded into the inner tube 22 (Step S704). Then, the outer tube 21 is evacuated to a lowest reachable pressure by the evacuation system 40 in order to eliminate air remaining inside the outer tube 21 and check for leakage.

After no leakage is confirmed, the N₂ gas is supplied to the inner tube 22 through the gas supplying pipes 26b, 26c, 26e, 26f from the gas supplying system 50. The N₂ gas flows toward the center of the disk boat 23 from the gas supplying pipes 26b, 26c, 26e, 26f, and flows out from the inner evacuation port 27 to the space between the inner tube 22 and the outer tube 21. Then, the N₂ gas is evacuated through the evacuation ports 25 by the evacuation system 40. While the N₂ gas flows in such a manner, the pressure control valve 44 is activated so that the pressure inside the outer tube 21 is adjusted at a predetermined pressure (Step S706).

Next, the disk boat 23 is rotated by the rotary motor 30a (Step S708). The rotation speed of the disk boat 23 may be determined in accordance with a deposition rate, the flow rates of the BTBAS gas and the gas, and may be about 100 revolutions per minute (rpm), for example.

After it is confirmed by a temperature sensor such as a thermocouple and a radiation thermometer (not shown) that the wafer temperature is stabilized at a predetermined deposition temperature, the BTBAS gas is supplied through the gas supplying pipe 26a (FIG. 5) from the gas supplying system 50 and the O₃ gas is supplied through the gas supplying pipe 26d (FIG. 5) from the gas supplying system 50 (Step S710). With this, the wafers W placed on the wafer disk 23b alternately traverse a BTBAS gas flow flowing from the gas supplying pipe 26a toward the slit 27f1 of the inner evacuation port 27, N₂ gas flows flowing from the gas supplying pipes 26b, 26c toward the inner evacuation port 27, and an O₃ gas flow flowing from the gas supplying pipe 26d toward the slit 27f2 of the inner evacuation port 27 in this order (see FIG. 5). By traversing in such a manner, BTBAS gas molecules and O₃ gas molecules are alternately adsorbed on the wafers W, and namely the MLD mode film deposition is realized.

After the disk boat 23 (wafer disk 23b) is rotated predetermined times corresponding to a predetermined thickness of the silicon oxide film to be deposited, the BTBAS gas and the O₃ gas are stopped and purged out from the inner tube 22 by the N₂ gas. Next, the outer tube 21 is evacuated to the lowest reachable pressure and then filled with the N₂ gas to the atmospheric pressure. Subsequently, the bottom plate 23e, the rotary motor 30a, the inner heater 24 and the disk boat 23 are lowered by the elevation mechanism 30b; the wafers W are unloaded from the disk boat 23 to the wafer cassette by the wafer loader (not shown); and thus the film deposition process is completed.

As described above, according to the film deposition apparatus 10 and the film deposition method using the film deposition apparatus 10 of an embodiment of the present invention, because the wafers W alternately traverse the flow paths of the source gas and the oxidizing gas that flow from the circumference to the center of the wafer disk 23b and are separated by the N₂ gas flow when the wafer disk 23b (disk boat 23) is rotated, the MLD mode film deposition is appropriately carried out. In addition, purging the reaction chamber 20 by alternately supplying the source gas and the oxidizing gas, which used to be necessary in a conventional MLD apparatus, is not required in the film deposition apparatus 10. Therefore, the process time can be reduced at least by the time required for such gas purging. In addition, because the process time can be reduced, a total amount of the gases used may be reduced accordingly, leading to reduced production costs. Moreover, opening/closing operations of valves for starting/stopping the source gas and the oxidizing gas are not required, thereby lengthening a working life of the valves, which may reduce maintenance costs of the film deposition apparatus 10 and thus the production costs.

In addition, in the film deposition apparatus 10 according to this embodiment of the present invention, because the flow paths of the source gas and the oxidizing gas are separated by the flow path of the N₂ gas, intermixing of the source gas and the oxidizing gas are effectively prevented, thereby certainly realizing the MLD mode film deposition.

Moreover, in the film deposition apparatus according to this embodiment of the present invention, because the gases flow from the circumference to the center of the circular wafer disk 23b, a gas flow cross section becomes smaller along the gas flow direction. Therefore, the gases flow in a converging manner, increasing a gas flow speed, toward the inner evacuation port 27, and is evacuated through the slit 27f1 of the inner evacuation port 27. Accordingly, the gases are not likely to remain or recirculate in the corresponding compartments defined by the partitioning plates 23p and the wafer disks 23b, and can be efficiently evacuated. In addition, the gas flow speed becomes higher toward the inner evacuation port 27, and any part of the gas is prevented from flowing from one compartment to the adjacent compartment through a gap between the portioning plate 23p and the inner evacuation port 27. Therefore, intermixing of the source gas and the oxidizing gas is prevented.

Furthermore, the BTBAS gas supplied from the gas supplying pipe 26a and the N₂ gas flowing through two adjacent compartments on both sides of the compartment where the BTBAS gas flows are evacuated through the slit 27f1 of the inner evacuation port 27, and the O₃ gas supplied from the gas supplying pipe 26d and the N₂ gas flowing through two adjacent compartments on both sides of the compartment where the O₃ gas flows are evacuated through the slit 27f2 of the inner evacuation port 27. Therefore, intermixing of the BTBAS gas and the O₃ gas is certainly prevented.

Furthermore, because the BTBAS gas and the O₃ gas can be separated even in the inner evacuation port 27 by the planar plate 27e, no deposition takes place in the inner evacuation port 27. Therefore, particles are not generated in the inner evacuation port 27, thereby reducing the wafer contamination.

In addition, in the film deposition apparatus 10 according to the embodiment of the present invention, because the number of the wafer disks 23b and/or the wafer receiving portions in the wafer disk 23b may be arbitrarily increased or decreased, the number of the wafers to be processed in one run may be adjusted in accordance with the intended throughput, thereby enhancing the usage efficiency of the film deposition apparatus 10.

Moreover, even when a larger wafer (e.g., a wafer having a diameter of 450 mm) is used in the film deposition apparatus 10 according to the embodiment of the present invention, because the wafer is placed on the wafer disk 23b, the film deposition apparatus 10 is advantageous in that wafer sagging is not a problem.

Furthermore, because the film deposition apparatus 10 according to the embodiment of the present invention is configured as a hot-wall type film deposition apparatus in which the outer heater 12 is arranged outside the outer tube 21, the temperature uniformity across the wafer can be improved. In addition, because the film deposition apparatus 10 is provided with the inner heater 24 below the disk boat 23, the temperature uniformity can be further improved.

While the present invention has been described with reference to the foregoing embodiments, the present invention is not limited to the disclosed embodiments, but may be modified or altered within the scope of the accompanying claims. For example, while the MLD of silicon oxide using the BTBAS gas and the O₃ gas has been described in the above embodiments, oxygen plasma may be used instead of the O₃ gas in other embodiments. In order to supply the oxygen plasma, an oxygen plasma generator is provided instead of the ozone generator 55 (FIG. 1), and microwaves or high frequency waves having a frequency of 915 MHz, 2.45 GHz, 8.3 GHz or the like are supplied to predetermined electrodes arranged inside the oxygen plasma generator, thereby generating the oxygen plasma.

Moreover, the film deposition apparatus 10 may be used to deposit a silicon nitride film rather than the silicon oxide film. In this case, ammonia (NH₃), hydrazine (N₂H₂) and the like may be utilized as a nitriding gas for the silicon nitride film deposition.

In addition, as a source gas for the silicon oxide or nitride film deposition, dichlorosilane (DCS), hexadichlorosilane (HCD), tris(dimethylamino)silane (3DMAS), tetra ethyl ortho silicate (TEOS), and the like may be used rather than BTBAS.

Moreover, the film deposition apparatus according to an embodiment of the present invention may be used for an MLD of an aluminum oxide (Al₂O₃) film using trymethylaluminum (TMA) and O₃ or oxygen plasma, a zirconium oxide (ZrO₂) film using tetrakis(ethylmethylamino)zirconium (TEMAZ) and O₃ or oxygen plasma, a hafnium oxide (HfO₂) film using tetrakis(ethylmethylamino)hafnium (TEMAHf) and O₃ or oxygen plasma, a strontium oxide (SrO) film using bis(tetra methyl heptandionate) strontium (Sr(THD)₂) and O₃ or oxygen plasma, a titanium oxide (TiO) film using (methyl-pentadionate)(bis-tetra-methyl-heptandionate) titanium (Ti(MPD)(THD)) and O₃ or oxygen plasma, and the like, rather than the silicon oxide film and the silicon nitride film.

In addition, the wafer receiving portion R of the wafer disk 23b may be configured as the predetermined number of positioning pins for positioning the wafer in a predetermined place on the wafer disk 23b.

Moreover, while the disk boat 23 has the plural wafer disks 23b in the film deposition apparatus 10 according to the above embodiment, the disk boat 23 may have only one wafer disk 23b. In addition, the film deposition apparatus 10 may have a susceptor having substantially the same configuration as the wafer disk 23b in other embodiments. In these cases, the outer tube 21 and/or the inner tube 22 may be made of, for example, stainless steel.

What is claimed is:

1. A film deposition apparatus comprising:
a reaction chamber evacuatable to a reduced pressure;
a substrate holding portion rotatably provided in the reaction chamber and configured to hold a substrate;
a first reaction gas supplying portion configured to flow a first reaction gas from an outer edge portion toward a center portion of the substrate holding portion;
a second reaction gas supplying portion configured to flow a second reaction gas from an outer edge portion toward a center portion of the substrate holding portion;
a separation gas supplying portion configured to flow a separation gas from an outer edge portion toward a center portion of the substrate holding portion, the separation gas supplying portion being arranged between the first and the second reaction gas supplying portions; and
an evacuation portion located in the center portion of the substrate holding portion in order to evacuate the first reaction gas, the second reaction gas, and the separation gas.

2. The film deposition apparatus of claim 1, wherein the substrate holding portion includes a substrate holding disk member having a substrate receiving portion in which the substrate is placed.

3. The film deposition apparatus of claim 2, wherein the substrate holding portion includes a plurality of the substrate holding disk members stacked with a predetermined clearance therebetween.

4. The film deposition apparatus of claim 2, wherein the substrate holding disk member includes a plurality of the substrate receiving portions arranged along a circumferential direction of the substrate holding disk member.

5. The film deposition apparatus of claim 4, wherein the substrate holding disk member includes a partitioning plate between two adjacent substrate receiving portions.

6. The film deposition apparatus of claim 2, wherein the substrate holding disk member includes a first opening in a center portion thereof, and
wherein the evacuation portion includes a cylindrical member inserted into the first opening of the substrate holding disk member, the cylindrical member having a second opening configured to allow a gas flowing over the substrate holding disk member to flow into an inside of the cylindrical member.

7. The film deposition apparatus of claim 6, wherein the cylindrical member includes a plurality of the second openings,
wherein a first one of the plural second openings is directed toward the first gas supplying portion, and
wherein a second one of the plural second openings is directed toward the second gas supplying portion.

8. The film deposition apparatus of claim 7, wherein the evacuation portion includes a planar plate member that divides an inner space of the cylindrical member into a first space in gaseous communication with the first one of the plural second openings and a second space in gaseous communication with the second one of the plural second openings.

9. A film deposition method comprising steps of:
placing a substrate on a substrate holding portion rotatably provided in a reaction chamber evacuatable to a reduced pressure;
rotating the substrate holding portion on which the substrate is placed;
flowing a first reaction gas from an outer edge portion toward a center portion of the substrate holding portion from a first reaction gas supplying portion;
flowing a second reaction gas from an outer edge portion toward a center portion of the substrate holding portion from a second reaction gas supplying portion;
flowing a separation gas from an outer edge portion toward a center portion of the substrate holding portion from a separation gas supplying portion arranged between the first and the second reaction gas supplying portions; and
evacuating the first reaction gas, the second reaction gas, and the separation gas from the center portion of the substrate holding portion.

10. A computer readable storage medium storing a computer program for causing a film deposition apparatus of claim 1 to perform a film deposition method comprising steps of:
placing a substrate on a substrate holding portion rotatably provided in a reaction chamber evacuatable to a reduced pressure;
rotating the substrate holding portion on which the substrate is placed;
flowing a first reaction gas from an outer edge portion toward a center portion of the substrate holding portion from a first reaction gas supplying portion;
flowing a second reaction gas from an outer edge portion toward a center portion of the substrate holding portion from a second reaction gas supplying portion;
flowing a separation gas from an outer edge portion toward a center portion of the substrate holding portion from a separation gas supplying portion arranged between the first and the second reaction gas supplying portions; and
evacuating the first reaction gas, the second reaction gas, and the separation gas from the center portion of the substrate holding portion.
